(19) United States
(12) Patent Application Publication
(10) Pub. No.: US 2004/0033703 A1
(43) Pub. Date: Feb. 19, 2004

(54) Method for forming amino-free low k material

(76) Inventor: Shyh-Dar Lee, Hsinchu Hsien (TW)

Correspondence Address: BIRCH STEWART KOLASCH & BIRCH, PO BOX 747, FALLS CHURCH, VA, 22040-0747, US

(21) Appl. No.: 10/222,918

(22) Filed: Aug. 19, 2002

(51) Int. Cl. H01L 21/31

(52) U.S. Cl. 438/790

(57) ABSTRACT

A method for forming an amino-free low k material. The method includes steps of introducing an amino-free gas into a chemical vapor deposition reactor; and decomposing the gas to form a layer of low k material. The amino-free gas is comprised of silane-based gas and CO₂. O₂ is also applicable as the process gas.

### BACKGROUND OF THE INVENTION

1. Field of the Invention

The invention relates generally to a method for fabricating semiconductor integrated circuits and more particularly to the formation of amino-free low dielectric constant (k) material using chemical vapor deposition.

Description of the Related Art

In current IC fabrication, connections between metal layers, such as copper, which are separated by dielectric interlevels, are typically formed with a damascene method of via formation between metal layers. The first metal pattern is first completely covered with dielectric, such as silicon dioxide. A trench is patterned into the dielectric layer. A via is patterned from the trench, through the dielectric layer, to the first metal pattern. A metal film, such as copper, is then used to fill the via and the trench. A layer consisting of dielectric with a metal via through it now overlies the first metal pattern. The excess metal can be removed using a CMP process to form a damascene metal structure.

As devices continue to become smaller, less expensive, and more powerful, smaller dimensions and denser packaging are required for integrated circuits. Consequently, fabrication process and selection of material become more and more important. The parasitic capacitor effect caused by inter-metal dielectric layer (IMD) has resulted in increasing RC delay. In order to reduce the capacitor effect, low-k material must be used. Examples material are fluorine-doped silicon oxide and organic polymer.

Currently, via first process is usually used to form dual damascene, where a via opening is formed through the inter-metal dielectric layer (IMD) before a trench is formed. However, the dielectric constant of IMD continues to shrink to less than 3. Under this circumstance, organic carbon used to provide lower dielectric constant than fluorine in dual damascene process causes problems, such as contamination of photoresist. This is caused by similar chemical properties of carbon and the photoresist. Therefore, some interaction occurs between carbon-doped CVD low k material and photoresist. Furthermore, existing amino element is the root cause for photoresist contamination when photoresist directly contacts the IMD layer. Consequently, a suitable process must be provided to prevent and avoid contact between carbon-doped CVD low k material and photoresist.

### SUMMARY OF THE INVENTION

In order to overcome the above problems, the invention provides a novel process for the formation of low k material by using amino-free gas, such as CO₂ and O₂, as the process gas.

It is another object of the invention to provide a method for forming low k material that reduces contamination with regards to photoresist.

Another object of the invention is to provide a method for forming low k material without unwanted side reactions.

It is yet another object of the invention to provide a method for forming low k material using conventional material without adding complexity to the process.

Another object of the invention is to provide a method for forming amino-free low k material in a dual damascene process.

In order to achieve the above objects, there is provided a method for forming low-k material, which comprises introducing an amino-free gas into a chemical vapor deposition reactor; and decomposing the gas to form a layer of low k material.

The method for forming amino-free low k material is also applicable in a dual damascene process, which comprises the steps of: a) placing a substrate into a chemical vapor deposition reactor and using an amino-free gas as process gas; b) decomposing the gas to form a layer of low k material as the intermetal dielectric layer on the substrate; c) forming a via through the intermetal dielectric layer by lithography; d) forming a photoresist layer on the intermetal layer which fills the via; e) patterning the photoresist layer so that an opening is formed over the via on the intermetal dielectric layer to expose and the top surface of the via and partial surface of the intermetal dielectric layer; f) etching the exposed intermetal dielectric layer to form a trench; g) removing the remaining photoresist layer; and h) filling the trench and via with inlaid copper to form dual damascene; and i) polishing the surface of the dual damascene to remove excess metal.

According to the method provided in the invention, the amino-free gas is a mixture of silane-based gas and CO₂, wherein the silane-based gas is the silicon source. However, other silicon sources can be used as well, for example, silicon dioxide. O₂ is also applicable as the process gas. Preferable carrier gases are Ar or He.

The chemical vapor deposition used in the present invention is selected from plasma enhanced chemical vapor deposition, electron cyclotron resonance chemical vapor deposition or induced coupling plasma chemical vapor deposition.

According to the method of the invention, the low-k material is amino-free. Without the presence of amino element, photoresist contamination between the photoresist layer and the intermetal dielectric layer is thus avoided. Also, no unwanted side reactions are induced, which consequently results in good process implementation. Furthermore, this method is cost effective.

The present invention will become more fully understood from the detailed description given hereinbelow and the accompanying drawings, given by way of illustration only and thus not intended to be limitative of the present invention.

### BRIEF DESCRIPTION OF THE DRAWINGS

FIGS. 1A˜1B illustrate the process of forming an amino-free low k material according to the invention.

FIGS. 2A˜2E illustrate the process of forming an amino-free low k material in a dual damascene process according to the invention.

### DETAILED DESCRIPTION OF THE INVENTION

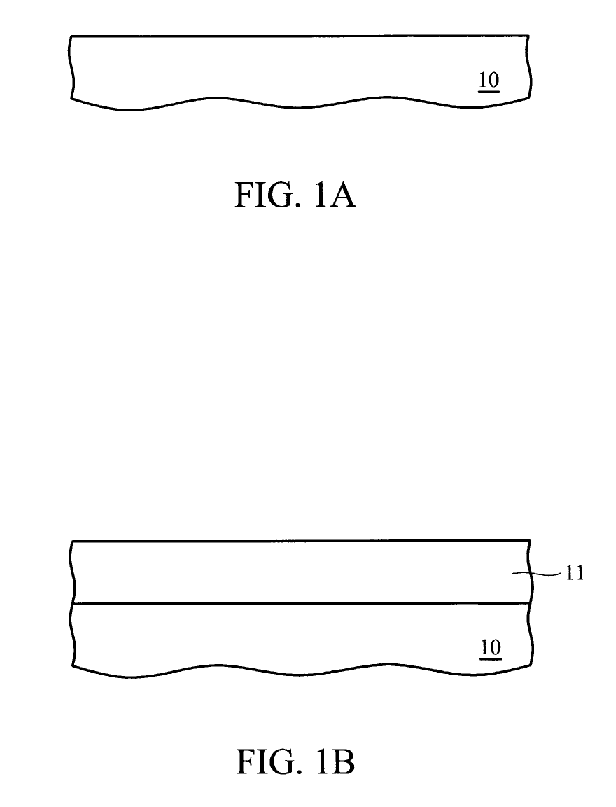

Firstly, as shown in FIG. 1A, a semiconductor substrate 10 is placed in a chemical vapor deposition chamber. The pressure within the chamber is preferably adjusted to 2.5 torr (chamber initial pressure). The semiconductor substrate 10 is then heated to a preferred temperature range of 250˜450° C.

Next, process gas comprised of CO₂ and silane with preferable carrier gas Ar or He mixed in a preferred ratio of 0.05˜0.2 (process gas/carrier gas) is introduced into the chamber. Preferable flowrate of the process gas is controlled at 200 sccm˜1 sLm. At this time, working pressure is preferably in the range of 2.5˜10 torr.

Then, chemical vapor deposition, such as plasma enhanced chemical vapor deposition (PECVD), electron cyclotron resonance chemical vapor deposition (ECRCVD) and inductor coupling plasma chemical vapor deposition (ICPCVD) is adopted to deposit a layer of amino-free low k material 11. Process gas at this stage is decomposed and deposited on the semiconductor substrate 10 to form the low k material layer 11.

Apart from CO₂, O₂ is also applicable as part of the process gas in the present invention.

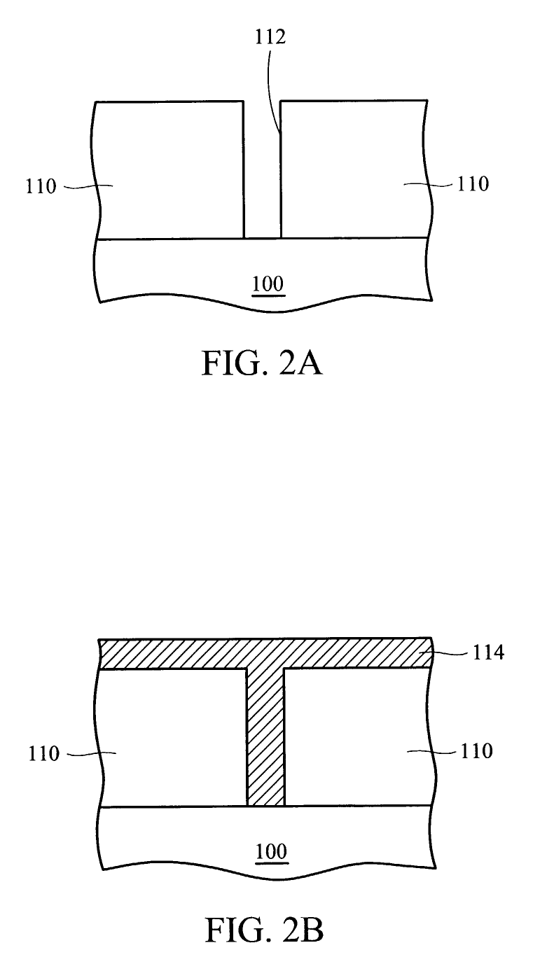

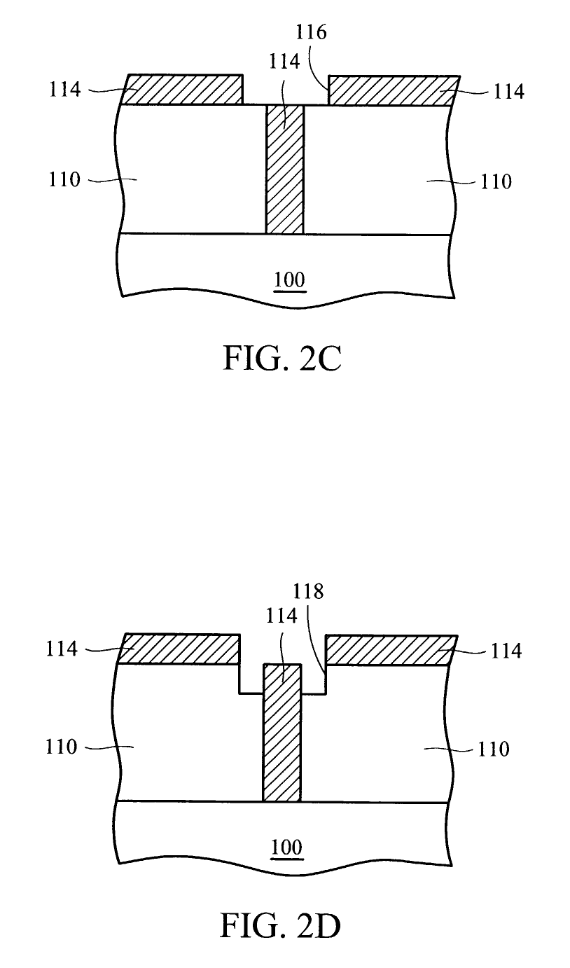

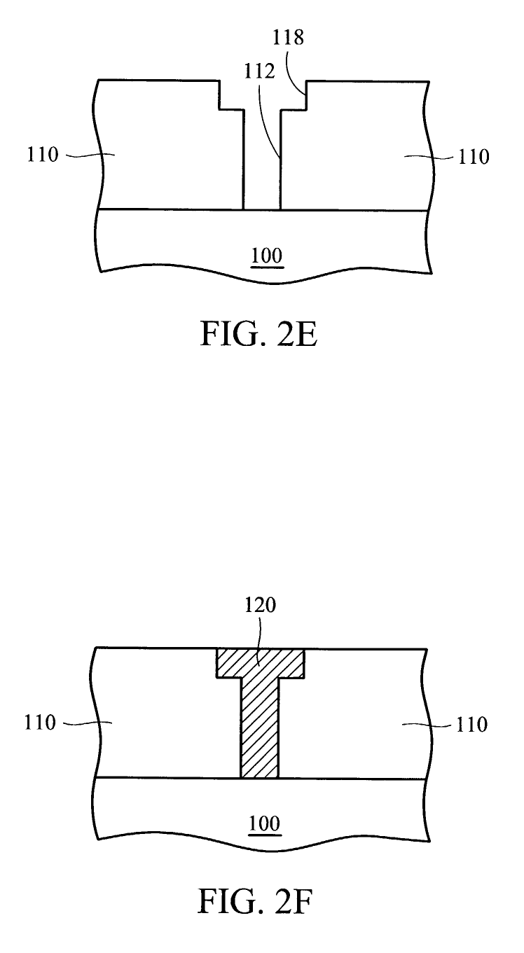

Another embodiment applying the method provided in the present invention in a dual damascene process is explained with references to FIGS. 2A˜2F. In FIG. 2A, a substrate 100 is provided. Amino-free gas is then used to form a low k material as the intermetal layer 110 on the substrate 100. Firstly, a semiconductor substrate 100 is placed in a chemical vapor deposition chamber. The pressure within the chamber is then preferably adjusted to 2.5 torr (chamber initial pressure). Temperature of the semiconductor substrate 10 is then heated to a preferred range of 250˜450° C.

Next, process gas comprised of CO₂ and silane with preferable carrier gas Ar or He mixed in a preferred ratio of 0.05˜0.2 (process gas/carrier gas) is introduced into the chamber. Flowrate of the process gas is preferably controlled at 200 sccm˜1 sLm. At this time, working pressure is preferably in the range of 2.5˜10 torr.

Then, chemical vapor deposition, such as plasma enhanced chemical vapor deposition (PECVD), electron cyclotron resonance chemical vapor deposition (ECRCVD) and inductor coupling plasma chemical vapor deposition (ICPCVD) is adopted to deposit a layer of amino-free low k material 110. Process gas at this stage is decomposed and deposited on the semiconductor substrate 100 to form the low k material layer 110. A via 112 is then formed by lithography as shown in FIG. 2A.

Next, in FIG. 2B, a photoresist layer 114 is formed on the intermetal dielectric layer 110 which fills the via 112. The photoresist layer 114 is then patterned to form an opening 116, wherein partial surface of the intermetal dielectric layer 110 and the top surface of the via are exposed as shown in FIG. 2C.

Next, in FIG. 2D, the exposed intermetal dielectric layer is etched away to form a trench 118 on top of the via 112 which is filled by the photoresist layer 114.

The remaining photoresist layer 114 is then removed, as shown in FIG. 2E, wherein the trench 118 and via 112 are formed.

Copper is then used to fill the trench 118 and via 112 to form a dual damascene 120, as shown in FIG. 2F.

According to the method provided in the present invention, amino-free process gas is used to form the low k material intermetal dielectric dielectric layer (IMD), thus potential contamination between the carbon-doped IMD material and the photoresist is avoided.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method for forming an amino-free low k material, comprising:
introducing an amino-free gas into a chemical vapor deposition reactor; and
decomposing the gas to form a layer of low k material.

2. The method as claimed in claim 1, wherein the amino-free gas is a mixture of silane-based gas and CO₂.

3. The method as claimed in claim 2, wherein the gas mixture also includes He or Ar as carrier gas.

4. The method as claimed in claim 2, wherein the mixture also includes O₂.

5. The method as claimed in claim 1, wherein the chemical vapor deposition reactor is plasma enhanced chemical vapor deposition, electron cyclotron resonance chemical vapor deposition or inductor coupling plasma chemical vapor deposition.

6. A method for forming an amino-free low k material in a dual damascene process; comprising:
a) placing a substrate into a chemical vapor deposition reactor and using an amino-free gas as process gas;
b) decomposing the gas to form a layer of low k material as the intermetal dielectric layer on the substrate;
c) forming a via through the intermetal dielectric layer by lithography;
d) forming a photoresist layer on the intermetal dielectric layer which fills the via;
e) patterning the photoresist layer so that an opening is formed over the via on the intermetal c layer to expose and the top surface of the via and partial surface of the intermetal dielectric layer;
f) etching the exposed inermetal dielectric layer to form a trench;
g) removing the remaining photoresist layer; and
h) filling the trench and via with inlaid copper to form a dual damascene; and
i) polishing the surface of the dual damascene to remove excess metal.

7. The method as claimed in claim 6, wherein chemical vapor deposition in steps (a) and (b) are carried out as plasma enhanced chemical vapor deposition, electron cyclotron resonance chemical vapor deposition or inductor coupling plasma chemical vapor deposition.

8. The method as claimed in claim 6, wherein the amino-free gas in step (a) is a mixture of silane-based gas and CO₂.

9. The method as claimed in claim 6, wherein the gas mixture in step (a) also includes He or Ar as carrier gas.

10. The method as claimed in claim 6, wherein the mixture in step (a) also includes O₂.
